(19) United States
(12) Patent Application Publication
(10) Pub. No.: US 2026/0231370 A1
(43) Pub. Date: Aug. 6, 2026

(54) LIQUID ENCLOSURE FOR THERMAL MANAGEMENT

(71) Applicant: LiquaCool IP LLC, Lakeside, MT (US)

(72) Inventors: Nicholas J. Monahan, Meadow Vista, CA (US); Clas Sivertsen, Kristiansund (NO)

(73) Assignee: LiquaCool IP LLC, Lakeside, MT (US)

(21) Appl. No.: 19/543,708

(22) Filed: Feb. 18, 2026

Related U.S. Application Data
(63) Continuation-in-part of application No. 19/334,749, filed on Sep. 19, 2025.
(63) Continuation-in-part of application No. 19/283,237, filed on Jul. 29, 2025.
(63) Continuation-in-part of application No. 19/047,555, filed on Feb. 6, 2025, now Pat. No. 12,652,780.

(51) Int. Cl. H05K 7/20

(52) U.S. Cl. CPC H05K 7/20327; H05K 7/20336; H05K 7/20381; H05K 7/2039

(57) ABSTRACT

A cooling system to provide thermal management comprising a substrate and an enclosure including an inflow connection and an outflow connection. The system includes a silkscreened pattern printed on the substrate for positioning and to provide sealing and a gasket seated on a top side of the substrate over the silkscreened pattern, the gasket encircling one or more components mounted on the substrate, wherein the gasket and the silkscreened pattern provide a leakproof connection between the enclosure and the substrate when the enclosure is fastened to the substrate. The system further includes a transfer fluid to flow into the enclosure through the inflow connection, and out of the enclosure through the outflow connection, the transfer fluid within the sealed enclosure contacting the one or more components mounted on the substrate and providing thermal management.

### RELATED CASES

The present application claims priority to U.S. patent application Ser. No. 19/047,555, filed Feb. 6, 2025, U.S. patent application Ser. No. 19/334,749, filed Sep. 19, 2025, and U.S. patent application Ser. No. 19/283,237, filed Jul. 29, 2025, and incorporates all of those applications in their entirety by reference.

### FIELD

The present invention relates to thermal management systems, specifically to a liquid enclosure to dissipate heat generated by electronic components.

### BACKGROUND

Integrated circuits (ICs) such as central processing units (CPUs), systems on a chip (SOCs), graphics processors (GPUs), tensor processing units (TPUs), neural processing units (NPUs), field-programmable gate arrays (FPGAs), and application-specific integrated circuits (ASICs), power transistors, DC-DC converters, power controllers with integrated switching transistors, triacs, thyristors, diode bridge rectifiers, insulated-gate bipolar transistors (IGBTs), voltage regulators, motor drivers, power factor correction (PFC) circuits, load switches, and others produce heat during operation. These components must be adequately cooled to maintain optimal performance and prevent failure.

In the prior art, various heat dissipation methods have been employed to absorb and remove heat from the ICs and redistribute it away from the hardware.

Traditionally, cooling methods have relied on a combination of heatsinks and fans, where air is moved across the heatsink to dissipate heat. However, such methods are often insufficient for managing the thermal demands of modern, high-performance components.

One prior art solution is liquid cooling. In this system, rather than air, a liquid such as water or a specialized dielectric fluid circulates to remove heat. The system generally consists of a baseplate connected to the metal lid of a CPU via thermal paste. The baseplate forms part of a water block that is filled with coolant. As the coolant absorbs heat from the baseplate, it is transferred through the water block and then routed to a radiator. At the radiator, the liquid is exposed to air for cooling, with fans often used to accelerate heat removal. The coolant then re-enters the water block, completing the cycle.

Semiconductor components exhibit a characteristic known as thermal runaway; wherein power consumption increases exponentially with rising temperature. As the die temperature rises, the power required to perform the same computational operations increases, exacerbating the thermal load. Without efficient heat removal, this thermal runaway can escalate, leading to critical temperature levels in semiconductor systems.

Traditionally, cooling semiconductor dies involves two approaches. The first involves heat dissipation through the top surface of the die, with thermal paste bridging the die to a metal heatsink, which is cooled by air or liquid. The second approach leverages ground pads connected to the package via gold wires, which are linked to the printed circuit board (PCB). This allows some heat to be transferred from the die through pins or balls to the PCB. Though relatively inefficient, even these incremental contributions help alleviate heat in high-performance systems.

The combined effect of these traditional cooling methods is in line with the principle of superposition, where every thermal gradient—any interface or material transition where temperature differences exist—contributes to reducing the internal temperature of the semiconductor die. Nevertheless, even with state-of-the-art conductive cooling techniques, high-performance semiconductor devices often exhibit internal die temperatures exceeding 100° C. in ambient environments of 30° C.

To further manage die temperature, many systems incorporate thermal sensors that monitor temperature levels and initiate throttling or other thermal management strategies when critical thresholds are approached.

While immersion cooling has been practiced for many years in the electronics industry, it presents several drawbacks because entire motherboards or subassemblies must be submerged in a liquid bath. In such configurations, interconnects, such as wires and cables, must exit the liquid, leading to complex and often cumbersome installations. Additionally, the need for large volumes of liquid makes the system expensive, prone to liquid loss through evaporation, and difficult to manage.

### BRIEF DESCRIPTION OF THE FIGURES

The present invention is illustrated by way of example, and not by way of limitation, in the figures of the accompanying drawings and in which like reference numerals refer to similar elements and in which:

FIG. 1A is an illustration of a simplified enclosure with an incorporated heatsink and couplings to allow a transfer fluid to exit the enclosure.

FIG. 1B is an illustration of a simplified enclosure with component contact areas with an incorporated heatsink and couplings to allow a transfer fluid to exit the enclosure.

FIG. 2A is an illustration of a simplified enclosure in which phase change is used for cooling.

FIG. 2B is an illustration of the top view of the simplified enclosure of FIG. 2A.

FIG. 3A illustrates a simplified enclosure with a foam to control sloshing of the transfer fluid, with cut-outs for the components.

FIG. 3B illustrates a simplified enclosure with a barrier to separate the gas and the liquid form of the transfer fluid.

FIG. 3C illustrates a simplified enclosure with a barrier to separate the gas and liquid, and with a foam to control sloshing of the transfer fluid.

FIG. 4A illustrates various configurations of using a wicking material for components inside the enclosure.

FIG. 4B illustrates one embodiment of using a pin grid array component with a wicking material acting as a thermal riser.

FIG. 5A illustrates one embodiment of the enclosure in combination with a thermal riser including wicking material.

FIG. 5B illustrates one embodiment of the enclosure in combination with a thermal riser including gas channels.

FIGS. 5C and 5D illustrate an embodiment of the thermal riser including grooves providing an escape path for gas.

FIG. 6 illustrates a configuration of using a wicking material across the enclosure.

FIGS. 7A and 7B illustrate embodiments of the system including a heat pipe.

FIG. 8 illustrates an embodiment of a plastic enclosure.

FIGS. 9A-9C illustrate a two-part enclosure in which the base of the enclosure is coupled to the substrate, and a gasket seals an upper portion of the enclosure to the base portion.

FIG. 10 illustrates one embodiment of the enclosure with a floating heatsink inside the enclosure.

FIG. 11A illustrates one embodiment of the enclosure with rotation insensitive connections.

FIG. 11B illustrates one configuration of a swivel connection for the coupling for rotation insensitivity.

FIG. 11C illustrates one configuration of a flexible connection for the coupling for rotation insensitivity.

FIGS. 11D and 11E illustrate one configuration of a flexible connection with an adjustable weight end to move the intake to the bottom, and the outflow to a top of the enclosure.

FIGS. 12A and 12B illustrate one embodiment of the system including a fluid stream director for directing flow at components within the enclosure.

FIGS. 12C and 12D illustrate one embodiment of the system including targeted jets for directing flow at components within the enclosure.

FIG. 13 illustrates one embodiment of the thermal management system that may be used with the enclosure.

### DETAILED DESCRIPTION

The present application describes a liquid enclosure for thermal management of one or more electronic components. The enclosure is filled with a transfer fluid which has a high heat transfer coefficient but is not electrically conductive (i.e. is electrically insulating). The transfer fluid may be a single phase or a two-phase fluid. The phase change of the transfer fluid may be used for heating or cooling the components. The system can provide board-level thermal management, cooling one or more components on a substrate. In various embodiments, the system can provide inter-chip cooling, which provides improved cooling by including inter-chip liquid flow-holes underneath components, ensuring that the transfer fluid makes contact with the bottom portion of one or more components on the substrate. The present system provides the advantages of immersion cooling but confines the cooling liquid only to a subset of the system. The subset of the system includes the components that require thermal management. The present system encloses the transfer fluid within a sealed system, ensuring that the transfer fluid does not leak or evaporate. The transfer fluid should not need replenishment over the product's lifetime.

Additionally, the enclosure can protect the components from radiation or interference, by providing a sealed enclosure. In some embodiments, the substrate and the enclosure together form a Faraday cage enclosing the components within the enclosure, and providing shielding for the components from radiation, radio or other signals, EMP waves, or other external signals that may damage or interfere with the components.

The following detailed description of embodiments of the invention make reference to the accompanying drawings in which like references indicate similar elements, showing by way of illustration specific embodiments of practicing the invention. Description of these embodiments is in sufficient detail to enable those skilled in the art to practice the invention. One skilled in the art understands that other embodiments may be utilized and that logical, mechanical, electrical, functional, and other changes may be made without departing from the scope of the present invention. The following detailed description is, therefore, not to be taken in a limiting sense, and the scope of the present invention is defined only by the appended claims.

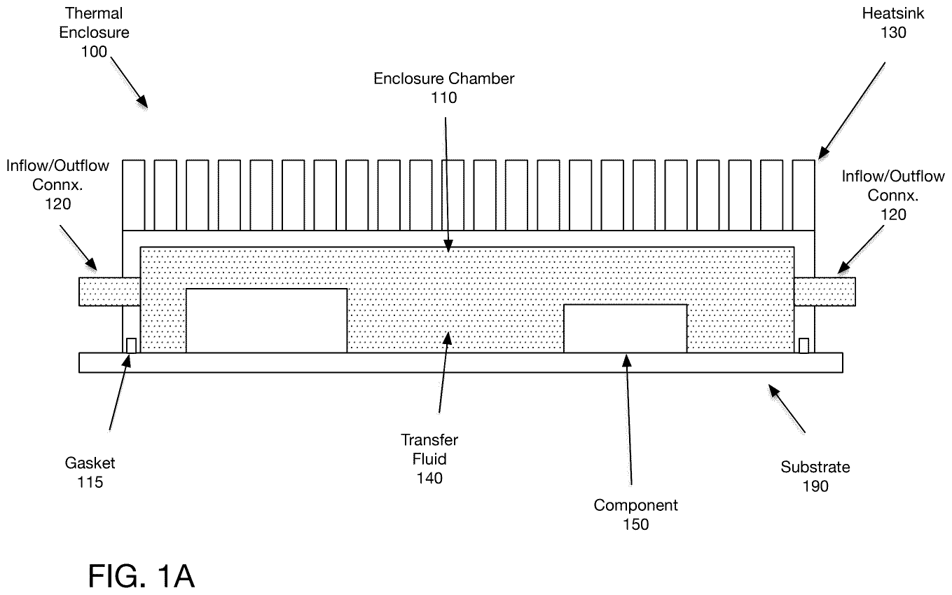

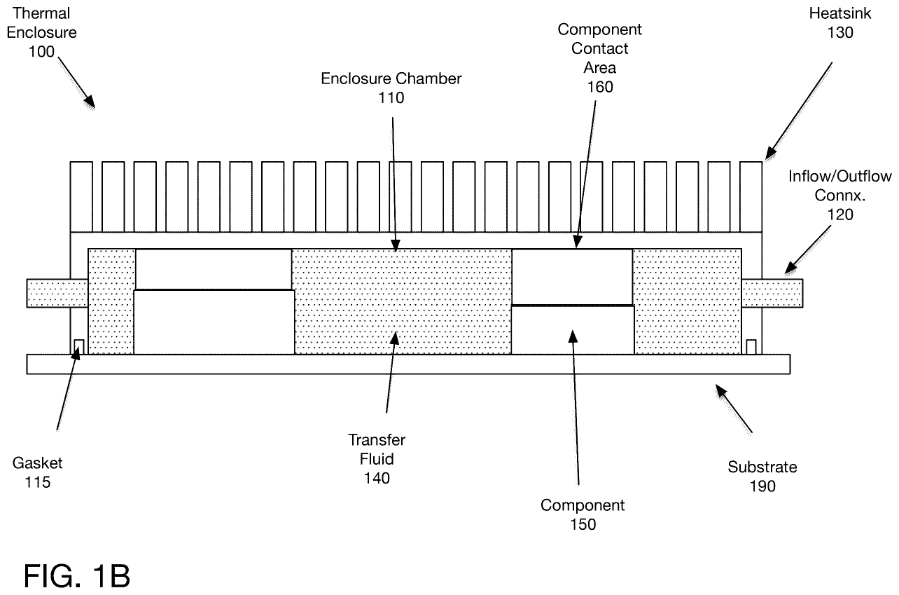

FIG. 1A is an illustration of a simplified enclosure with an incorporated heatsink and couplings to allow a transfer fluid to exit the enclosure. The thermal enclosure 100 comprises an enclosure chamber 110 coupled to a substrate 190. The enclosure chamber 110 encloses one or more components 150 mounted on the substrate. The enclosure chamber 110 is sealed to the substrate 190 using gaskets 115 which extend around the enclosure. In some embodiments, the gasket 115 is seated on a top side of the substrate and sealed against a silkscreened pattern printed onto the substrate encircling the area defined by the enclosure chamber 110. In some embodiments, the silkscreened pattern is a double layer of silkscreen printing, to provide a smooth surface for sealing without any microscopic gaps. The silkscreen pattern in one embodiment provides positioning for the enclosure, as well as sealing of the enclosure chamber. The gasket is a round rubber component, in one embodiment, which is flexible and compliant, and is compressed when the enclosure chamber 110 is fastened to the substrate 190 to form a leakproof seal. The gasket seals against the silkscreened layer to provide a leakproof connection, in some embodiments. In some embodiments, the system includes two silkscreen lines in close proximity, such that the gasket is positioned between the two silkscreen lines, and when compressed the gasket seals against both silkscreen lines.

The chamber 110 is filled with a transfer fluid 140 which is used to cool components 150. The transfer fluid is an electronics coolant liquid that is electrically insulating and stable. The transfer fluid in various embodiments is a two-phase fluid, with a boiling point set based on an expected temperature of the components 150 in operation. Thus, the transfer fluid 140 in some embodiments is a perfluorinated compound (PFC) or perfluorocarbons. In some embodiments, the transfer fluid may be 3M™ Fluorinert™ Liquid FC-72, which is a non-conductive, thermally and chemically stable fluid which can be used single and two phase low temperature heat transfer. In some embodiments, a more environmentally safe material is used such as InnoChill™ Immersion Cooling Fluid, ElectroCool™ from Engineered Fluids™, or another type of dielectric coolant. The transfer fluid 140 may be a single phase fluid, instead of a two phase fluid, in some embodiments.

Most of the volume of the enclosure chamber 110 is filled with the transfer fluid in liquid form, however if the transfer fluid 140 is a two phase fluid, there is enough space left in the enclosure to allow the expansion as the transfer fluid turns into gas. A two-phase transfer fluid is designed to transition between phases from liquid to gas in specific locations where it is heated above its boiling point and then turn back into liquid again as the gas flows into a region where it is cooled down below the boiling point. In some embodiments, the transition from liquid to gas provides much of the cooling. The transfer fluid 140 flows through the enclosure chamber 110, through inflow/outflow connections 120. The transfer fluid entering through the inflow connection is cooler, and the transfer fluid exiting through the outflow connection is warmer, having transferred some of the heat from the components 150 to the transfer fluid itself. The transfer fluid flow rate may be between 0 and 5 gallons per minute. Although only a single inflow/outflow connection 120 is shown, in some embodiments, there may be multiple connections for both inflow and outflow. In some embodiments, the top of the enclosure chamber 110 may have a heatsink 130 to further provide cooling to the transfer fluid 140 within the chamber. The heatsink 130 may be coupled to the top of the enclosure chamber 110, in some embodiments. In other embodiments, the heatsink may be integral with the enclosure chamber, rather than a separate attached component. The simplified heatsink 130 shown in the illustration shows fins. However, fingers or other structures to dissipate heat may be used. The relative height of the heatsink 130 may be less than the height of the enclosure chamber 110.

The enclosure chamber 110 may be made of a heat conductive material, such as aluminum, copper, etc. In some embodiments, the enclosure chamber 110 may include multiple materials or alloys. In some embodiments, the enclosure chamber 110 may be non-metallic.

FIG. 1B is an illustration of a simplified enclosure with component contact areas with an incorporated heatsink and couplings to allow a transfer fluid to exit the enclosure. In this configuration, the enclosure chamber 110 includes component contact areas 160 which create a physical contact between the top of the enclosure chamber 110 and the components 150. In some embodiments, there may be thermal grease or other such heat transferring material between the component contact area and the component. The position and size of the component contact areas 160 matches the position and sizes of the corresponding components.

In this configuration, the heat produced by components 150 is dissipated through contact with the transfer fluid 140 as well as through direct contact with the component contact area 160. The component contact area 160 may be made of a highly heat conductive material, such as red copper. In some embodiments, the component contact area 160 may extend through the top of the enclosure chamber 110, placing the component contact area 160 into direct contact with the outside air for additional cooling. In some embodiments, a subset of the components 150 may have component contact areas 160. For example, in some embodiments, only the components which produce the most waste heat, such as GPUs or CPUs, may have component contact areas 160 while other components within the enclosure chamber 110 are cooled only by the transfer fluid 140.

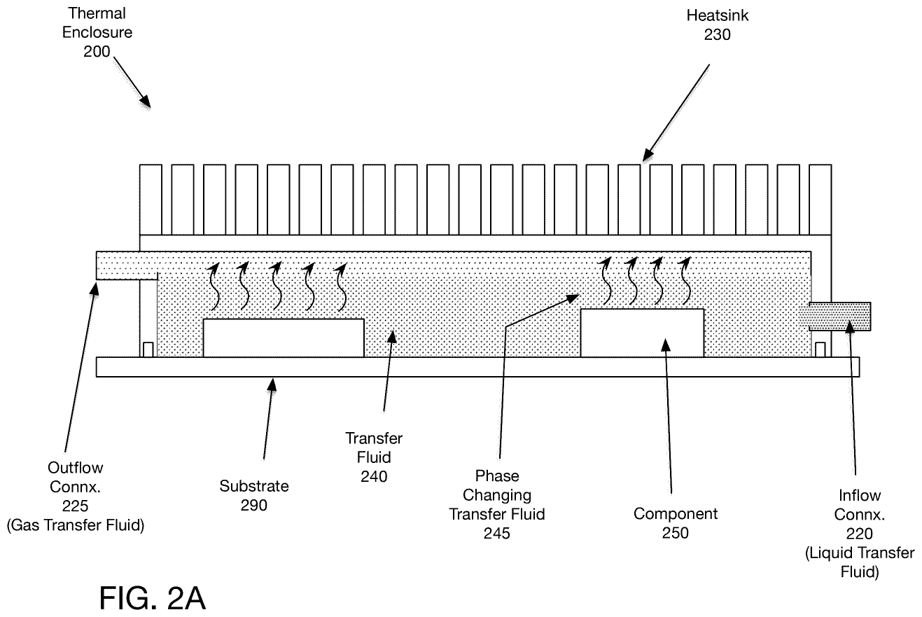

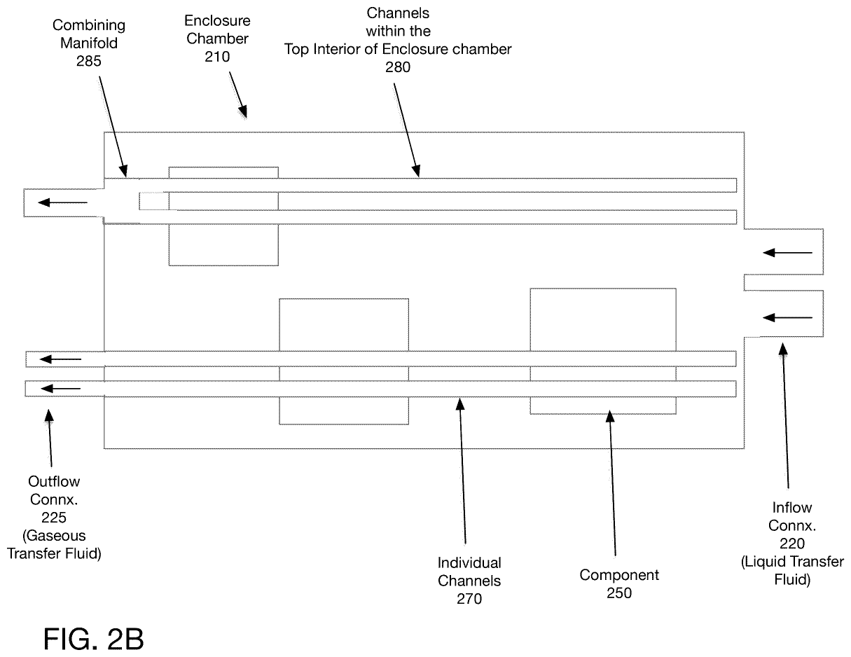

FIGS. 2A and 2B are an illustration of a simplified enclosure in which phase change is used for cooling. This illustration shows the enclosure chamber on a substrate 290, filled with a two-phase transfer fluid 240. The enclosure may include a heatsink 230. The transfer fluid enters through inflow connection 220, in liquid form, and at a first temperature. As it flows through the enclosure 210, it comes into contact with a component 250, which produces heat. The transfer fluid 240 has a boiling point set such that the transfer fluid turns to gas 245 at the temperature produced by a component 250. As the transfer fluid turns to gas, it rises within the chamber, to the top of the chamber. The outflow connection 225 is at the top of the chamber, such that the outflow is primarily the gaseous transfer fluid. The inflow connections 220 are at the bottom of the enclosure and provide inflow of the cold transfer fluid.

There are outflow connections 225 in the top of the enclosure, to direct the gaseous transfer fluid, after phase change, out of the enclosure. In some embodiments, there may be individual channels 270 as shown which exit separately from the chamber. In some embodiments, there may be channels 280 which are combined with a combining manifold 285 within the enclosure. While only four channels 270, 280 are shown in this illustration in one embodiment an implementation may have any number of channels, including a single wide channel, or many narrow channels. The channels may not be located over the components and may be distributed evenly through the top of the enclosure 200. In some embodiments, the channels 270, 280 may be etched or cut into the top of the enclosure. In some other embodiments, the channels 270, 280 may be formed by the top of the enclosure having a patterning that provides a path for the gaseous transfer fluid out of the enclosure.

While in this illustration most of the transfer fluid exiting the enclosure is gaseous, some of the transfer fluid may be in liquid form. Once the transfer fluid exits the enclosure, it passes to a cooling system (not shown) which cools the transfer fluid and recirculates it to the inflow connection. In some embodiments, multiple enclosures may share the same cooling system.

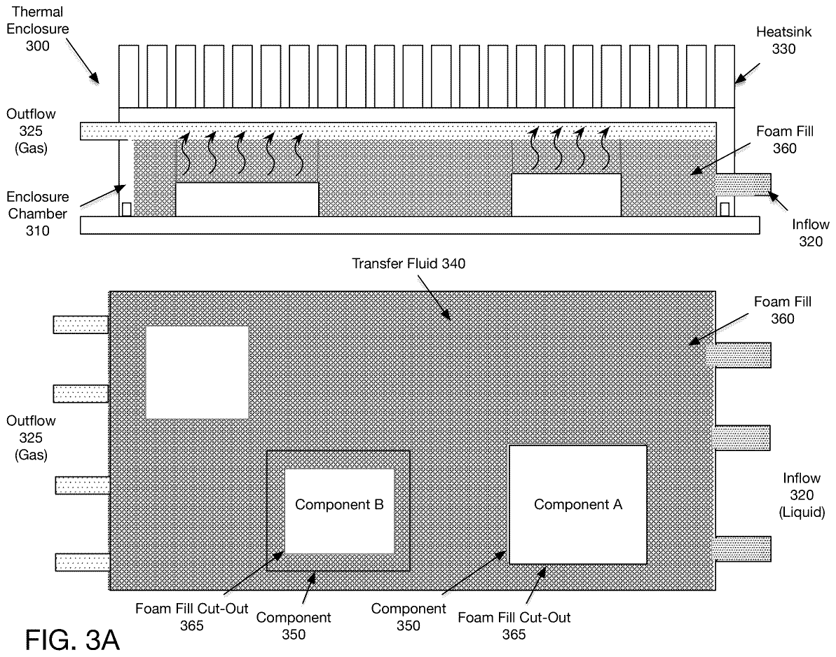

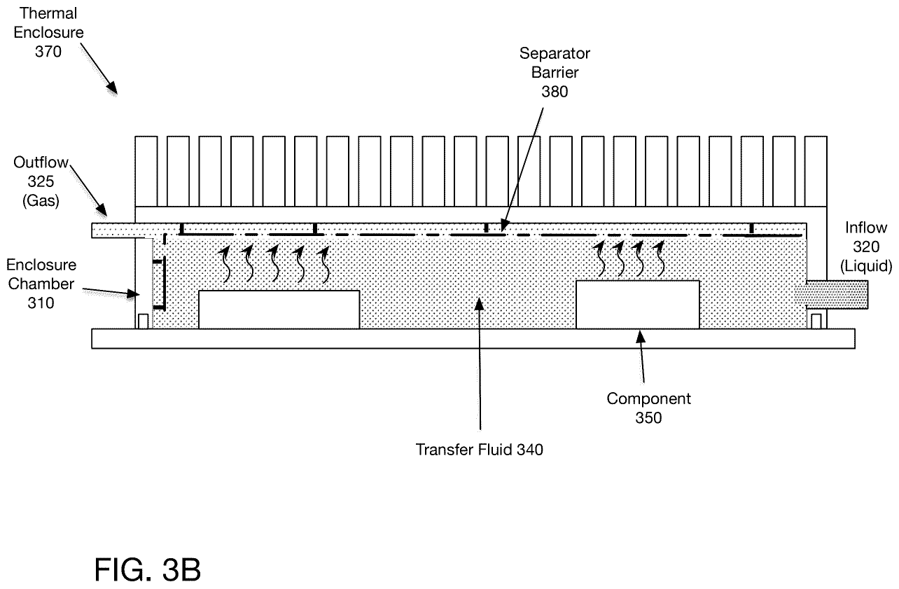

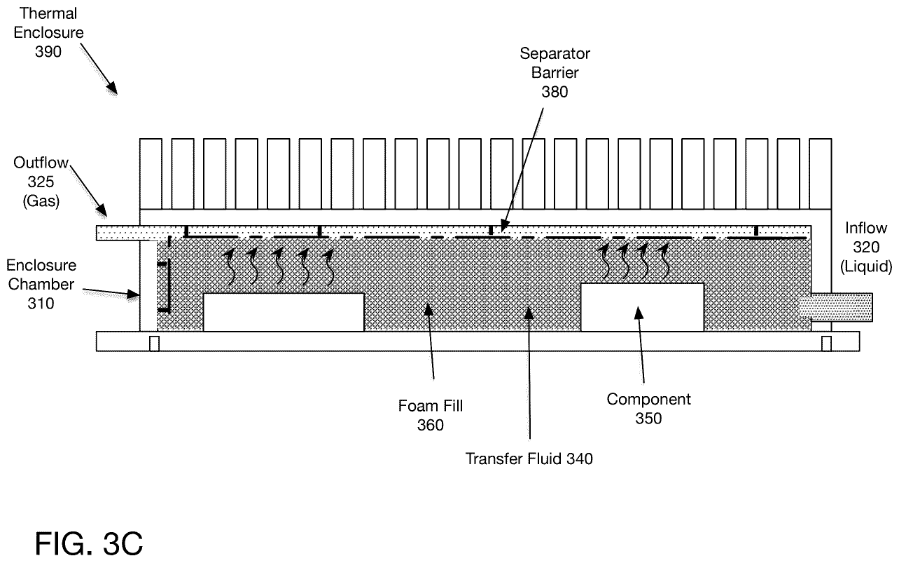

FIG. 3A illustrates a simplified enclosure with a foam to prevent sloshing of the transfer fluid, with cut-outs for the components. In this configuration of the thermal enclosure 300 on the substrate 390, there is an inflow 320 and outflow 325 of transfer fluid which passes through the enclosure chamber 310. The thermal enclosure 300 may also include a heatsink 330. The interior of the enclosure chamber 310 includes a plurality of components 350, which produce heat in operation. The transfer fluid 340 is used to cool the components 350.

The interior of the enclosure chamber 310 is filled with a foam fill 360, which provides protection against sloshing of the transfer fluid. In some embodiments, the foam fill 360 is a non-conductive foam. In some embodiments, the foam fill is made of polymer foam, such as polypropylene (PP) foam. The foam fill 360 in some embodiments leaves a portion of the chamber 310 empty for the transfer fluid 340 which has turned to gas to leave the chamber 310, through outflow 325. In some embodiments, the foam fill 360 fills the entirety of the chamber 310 not occupied by components. In some embodiments, the outflow 325 is designed to primarily have gas leave the chamber.

In some embodiments, there are cut-outs 365 in the foam fill above some or all of the components. The cut-outs 365 provide a path for the gaseous transfer fluid 340 to rise from the component to the top of the enclosure chamber 310.

In some embodiments, the foam fill cut-outs 365 are the same size as the component, as shown for component A. In some other embodiments, the cut-out 365 may be smaller than the full size of the component it is covering, as shown for component B.

FIG. 3B illustrates a simplified enclosure with a barrier to separate the gas and the liquid form of the transfer fluid. In this configuration, the thermal enclosure 370 includes a separator barrier 380 to separate the portion of the transfer fluid 340 which is gas from the portion which is liquid. The separator barrier 380 in one embodiment is a layer coupled to one or more of the walls of the enclosure chamber 310 and includes openings for the gas to pass through.

In some embodiments, the separator barrier 380 has numerous small holes through which the gaseous transfer fluid 340 is designed to pass. The separator barrier 380 is designed to reduce sloshing of the transfer fluid, as the liquid transfer fluid flows into the enclosure chamber 310 and the gaseous transfer fluid exits the enclosure chamber through outflow 325. In some embodiments, the separator barrier 380 is in very close proximity to the top of the chamber 310, leaving only a narrow area for the gas to escape. The outflow connection 325 in one embodiment is sized to the area on top of the separator barrier 380. In some embodiments, the separator barrier 380 is coupled to the top of the enclosure. In some embodiments, the area above the separator barrier 380 is defined by channels through which the gaseous transfer fluid can escape. Thus, in some embodiments, the separator barrier 380 is attached to a top of the enclosure with the area above the separator barrier 380 including the channels in the top of the chamber 310 through which gas can escape. The outflow 325 thus is primarily the gaseous transfer fluid. In some embodiments, in this configuration a sensor within the chamber 310 ensures that the inflow is regulated so that the pressure in the chamber does not increase above a threshold. As will be discussed in more detail below, some or all of the configurations may include such sensors, and valves, to control the inflow and outflow rates to optimize the cooling. Additionally, in some embodiments, jets or pumps may be used to direct flow to particular areas within the enclosure, to components or subparts of components which are identified as needing additional cooling.

FIG. 3C illustrates a simplified enclosure with a barrier to separate the gas and liquid, and with a foam to control sloshing of the transfer fluid. In this configuration, the foam fill 360 discussed with respect to FIG. 3A and the separator barrier 380 discussed with respect to FIG. 3B are combined. There may be cut-outs in the foam fill 360, as discussed with respect to FIG. 3A.

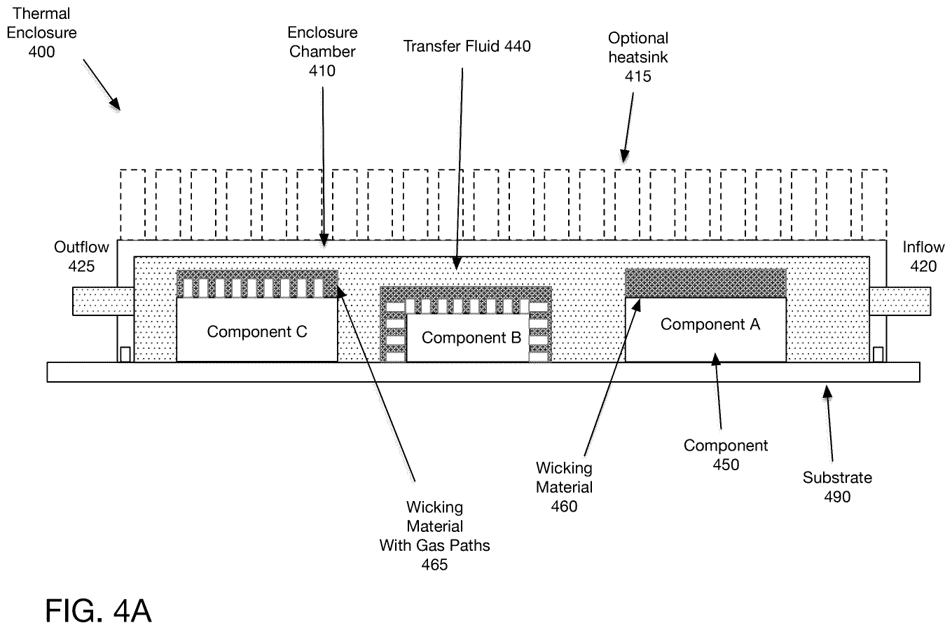

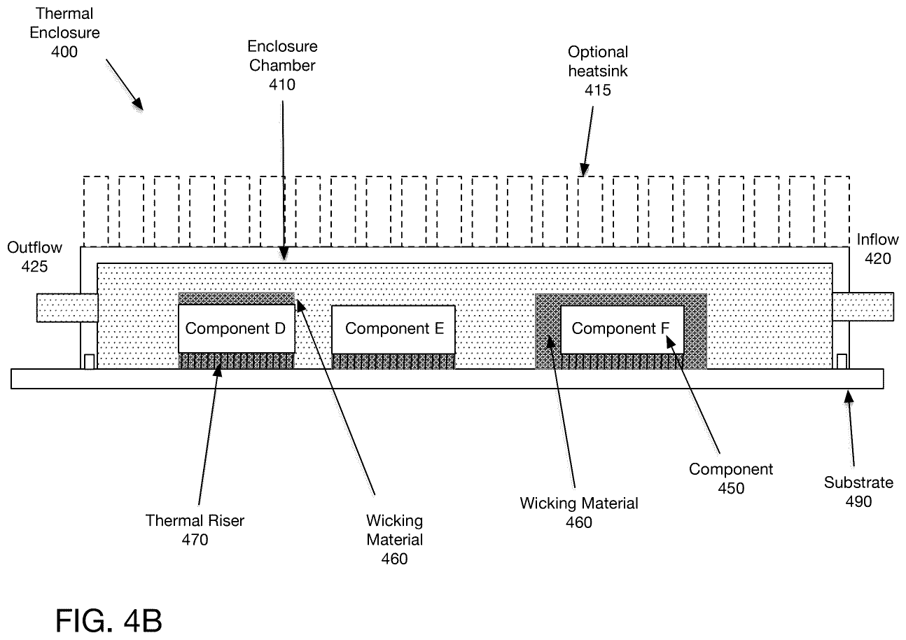

FIG. 4A illustrates various configurations of using a wicking material for components inside the enclosure. The thermal enclosure 400 includes chamber 410 and optionally heatsink 415 on substrate 490. The chamber 410 includes an inflow 420 and outflow 425 for transfer fluid 440. Each of the components 450 illustrate include associated wicking material 460. In some embodiments, the wicking material may be a metal mesh, porous Polytetrafluoroethylene (PTFE), a glass or ceramic wick, or another material which can be used to pull transfer liquid.

The wicking material 460 may be on top of the component, as shown for component A and component C, or may surround the top and one or more sides of the component, as shown for component B. The wicking material 460 may include gas paths 465, as shown for Component B and Component C. The gas paths 465 are gaps within the wicking material for the gaseous transfer fluid to escape. The wicking material pulls transfer fluid to the component and provides a nucleation surface to ensure that the transfer fluid provides cooling to the component. Using wicking material 460 also provides rotation insensitivity, since the transfer fluid flow is pulled to the component regardless of the orientation of the substrate 490. The wicking material encourages nucleation and avoids the gaseous transfer fluid creating a layer of hot gas on top of the component 450 which keeps the transfer fluid from coming in thermal contact with the component 450, reducing heat transfer. In some embodiments, the wicking material is made from non-conductive metallic fibers.

FIG. 4B illustrates one embodiment of using a pin grid array component with a wicking material acting as a thermal riser. In this configuration, the wicking material is between the components 450 and the substrate 490, acting as a thermal riser 470. In one embodiment, the thermal riser 470 includes wicking material and is part of a pin grid array component which connects the contacts of the component to traces on the substrate.

The thermal riser 470 is positioned between the component 450 and the substrate 490. The thermal riser 470 has pins coupled to each of the component interconnection pins of the component 450. The component interconnection pins may be BGA (ball grid array) connectors, or other types of connectors designed to be coupled to pads on the substrate 490. The thermal riser 470 provides pins which connect the connectors to the pads. The pins, in some embodiments, may be copper. In some embodiments, the pins may be gold plated. The pins, in some other embodiments may be of another highly conductive material. The interior of thermal riser 470 includes the transfer fluid, which provides cooling to the component interconnection pins, and thus to the bottom of the components 450. In one embodiment, the thermal riser component described in co-pending application XYZ, filed on XYZ, entitled XYZ is used. That application is incorporated in its entirety.

In one embodiment, the thermal riser 470 is filled with the wicking and nucleation material. In some embodiments, as shown with respect to component D, there may be additional wicking material 460 on top of the component as well. In some embodiments, as shown with respect to component F, the wicking material 460 may surround the entire component. In one embodiment, the wicking material is a non-conductive material with fibers to encourage nucleation and avoid the gaseous transfer fluid creating a layer of hot gas which keeps the transfer fluid from coming in contact with the component 450, reducing heat transfer.

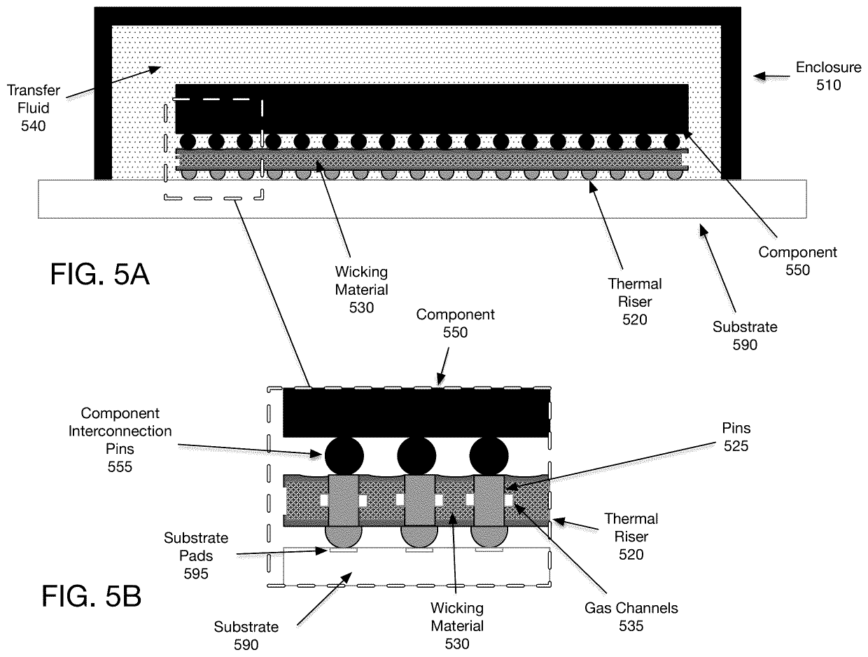

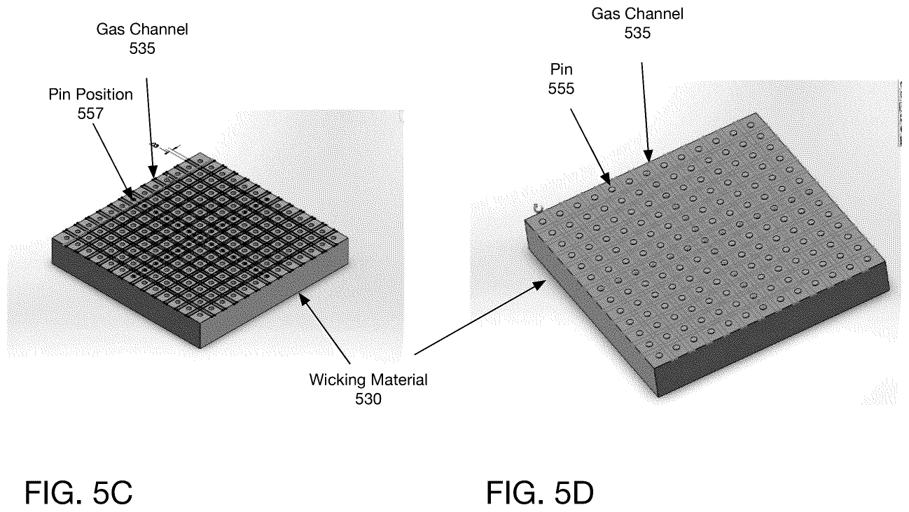

FIGS. 5A and 5B illustrate one embodiment of the enclosure in combination with a thermal riser including wicking material. The enclosure 510 is coupled to a substrate 590. Although not shown, the enclosure includes one or more of a heatsink on top of the enclosure, a heat pipe, or an inflow and outflow connection, to cool the transfer fluid 540 within the enclosure. A component 550 is enclosed within the enclosure 510. In this illustration a single component is shown, however the enclosure may be around one or more components, as shown in other figures.

The component 550 is situated on a thermal riser 520. The thermal riser 520 couples the component 550 electrically to the substrate. It is interposed between the ball grid array or other connector components of the component 550 and the pads on the substrate to which those connectors are coupled. The thermal riser 520 includes pins 525 connecting the component's individual interconnection pins 555 with the corresponding pads 595 of substrate 590. This allows the electrical connection between the component 550 and substrate 590.

The interior of the thermal riser 520 is open to the enclosure 510 and includes wicking material 530. The wicking material 530 pulls the transfer fluid 540 into the thermal riser 520 and provides a surface for nucleation. In some embodiments, the thermal riser wicking material includes gas channels 535, which allow the transfer fluid which turns to gas to more easily escape the thermal riser 520.

FIGS. 5C and 5D illustrate an embodiment of the thermal riser including grooves providing an escape path for gas. The wicking material forming the thermal riser includes pins, and the top surface includes gas channels 535. FIG. 5C illustrates an embodiment of the wicking material showing the pin positions 557 without the pins, and FIG. 5D shows the pins.

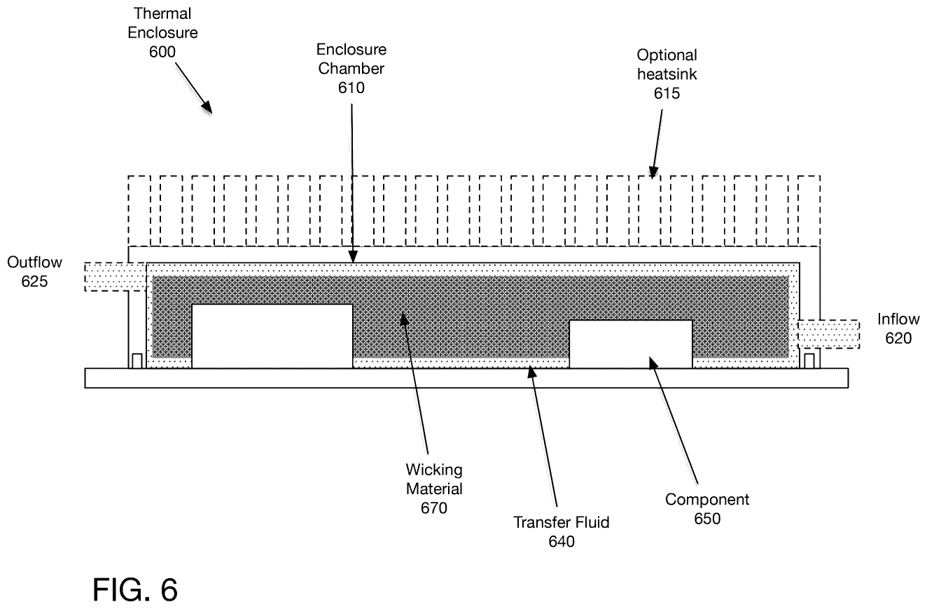

FIG. 6 illustrates a configuration of using a wicking material across the enclosure. In this configuration, the thermal enclosure 600 includes the enclosure chamber 610 and an optional heatsink 615. The components 650 are surrounded by transfer fluid 640. Some or all of the enclosure chamber 610 is filled with wicking material 670. In some embodiments, as discussed above with respect to the foam, there may be cut-outs in the wicking material above the components. In some embodiments, as discussed above with respect to the wicking material, the material may include gas paths near the components to allow the gaseous transfer fluid to rise to the top of the enclosure chamber 610, to encourage heat exchange. In some embodiments, the wicking material 670 leaves a small gap at the top and bottom of the enclosure chamber 610 to encourage transfer fluid inflow, through inflow 620, and gaseous transfer fluid outflow through outflow 625.

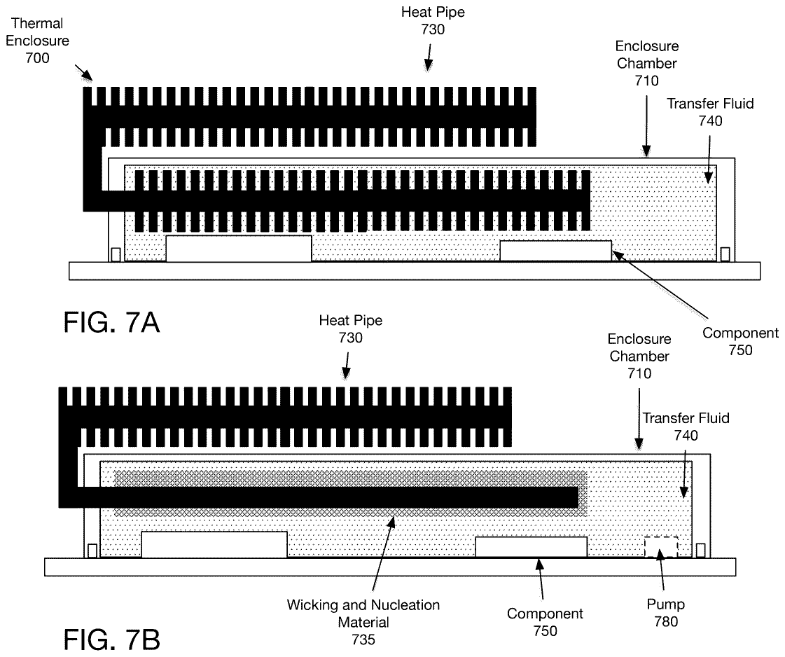

FIGS. 7A and 7B illustrate embodiments of the system including a heat pipe. In this configuration the thermal enclosure 700 includes an enclosure chamber 710 filled with transfer fluid 740 and a heat pipe 730. The heat pipe 730 may be used to cool the transfer fluid 740 in the chamber 710. In this configuration, in some embodiments, there may not be an inflow or an outflow for form the chamber. Thus, the transfer fluid may remain in the chamber once enclosed, and the heating may rely on the heat pipe 730. In some embodiments, in this configuration there may be a pump 780 to ensure that the transfer fluid circulates within the enclosure and provides cooling to components 750.

In some embodiments, the heat pipe 730 has two portions, an interior portion within the enclosure chamber 710 and an exterior portion outside the enclosure chamber 710. The outside portion may include heatsink fins or pins to increase cooling capacity. Additionally, one or more fans (not shown) or other means of flowing cold air through the exterior portion of the heat pipe 730 may be utilized. The interior portion of the heat pipe may include a heatsink as well, as shown in FIG. 7A. Alternatively, the interior portion of the heat pipe 730 may include wicking and nucleation material 735. The wicking and nucleation material may be a metallic foam. The metal foam may be aluminum foam, having a porous structure to provide voids through which the transfer fluid can flow, while providing structure for wicking and nucleation.

Although these examples illustrate the heat pipe 730 used with an enclosure chamber 710 which does not include inflow and outflow components, in some embodiments the heat pipe may be combined with the inflow and outflow features discussed above. In some embodiments, there may be a pump within the enclosure, to improve the movement of the transfer fluid within the enclosure.

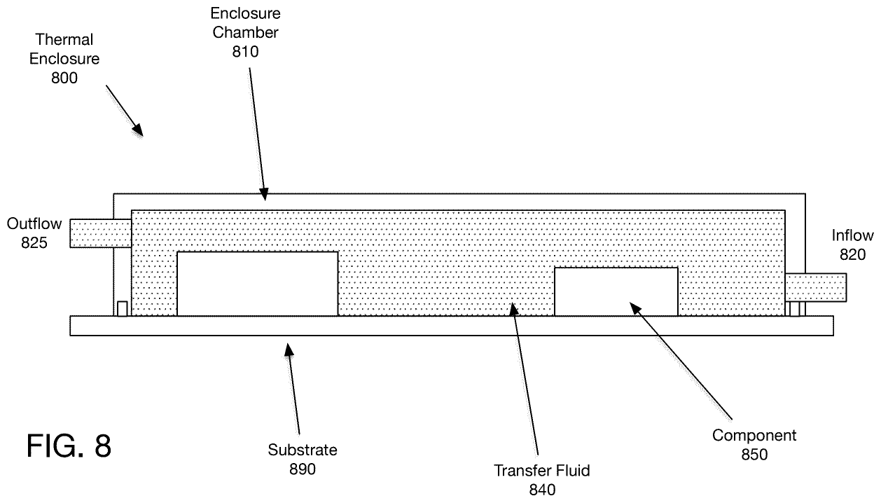

FIG. 8 illustrates an embodiment of a plastic enclosure. In this configuration, the thermal enclosure 800 includes an enclosure chamber 810 made of an alternative material which does has lower heat transfer capability. For example, plastic, transparent polymer, ceramic, transparent aluminum such as aluminum oxynitride (ALON), or another material may be used. The use of a plastic enclosure moves the heat transfer entirely to the transfer fluid 840. In some embodiments, this would lead to an increased flow-through rate through inflow 820 and outflow 825, to ensure that components 850 receive an adequate level of cooling. The use of a plastic enclosure or other limited thermal conductivity enclosure may be useful when the substrate 890 is weight limited, or the enclosure needs to be not electrically conductive, for example where the system is in a location where there may be electrical power in the environment.

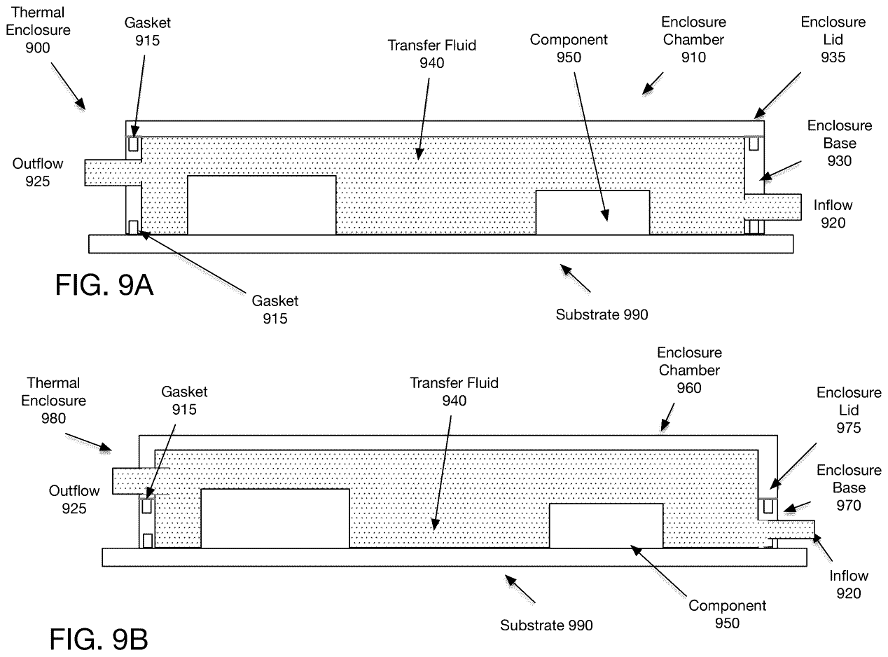

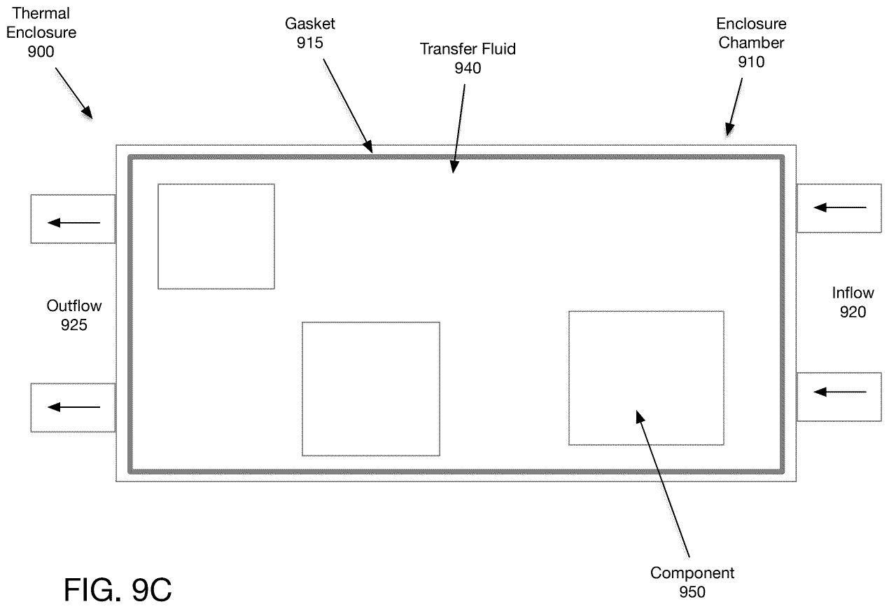

FIGS. 9A-9C illustrate a two-part enclosure in which the base of the enclosure is coupled to the substrate, and a gasket seals an upper portion of the enclosure to the base portion. In this configuration, the enclosure base 930 is coupled to the substrate 990. In one embodiment, gaskets 915 may be used for coupling the enclosure base 930 to the substrate 990. In some embodiments, the enclosure base 930 may be glued to the substrate 990.

The enclosure lid 935 is then coupled to the enclosure base 930. There may be a second gasket 915 used between the enclosure base 930 and the enclosure lid 935. In some embodiments, the enclosure lid 935 may be glued to the enclosure base 930. In some embodiments, only one of the connections may be permanently bonded via glue or another material - the enclosure base 930 may be permanently bonded to one of the enclosure lid 935 or the substrate 990, to provide the ability to open the enclosure, if needed.

The enclosure base 930 and enclosure lid 935 together form the enclosure 900, and a sealed enclosure chamber 910. The sealed enclosure chamber 910 is filled with transfer fluid 940, used to provide thermal management to components 950. The enclosure chamber 910 may include an inflow 920 and outflow 925, to enable the heated transfer fluid to leave the chamber 910, and new transfer fluid to enter the chamber. This configuration permits the attachment of the enclosure base 930 during an initial assembly, with the addition of the enclosure lid 935 may be added at the last assembly step. In some embodiments, this configuration may be used with the wicking materials or foam fill described above. Using a two-part enclosure enables the insertion of the foam fill or wicking material more easily.

FIG. 9B illustrates the two-part enclosure 980, in which the enclosure chamber 960 is made of an enclosure base 970 that is shorter and the enclosure lid 975 includes a flat lid portion as well as walls which are designed to be coupled to the enclosure base 970. FIG. 9C illustrates a top view of the two-part enclosures.

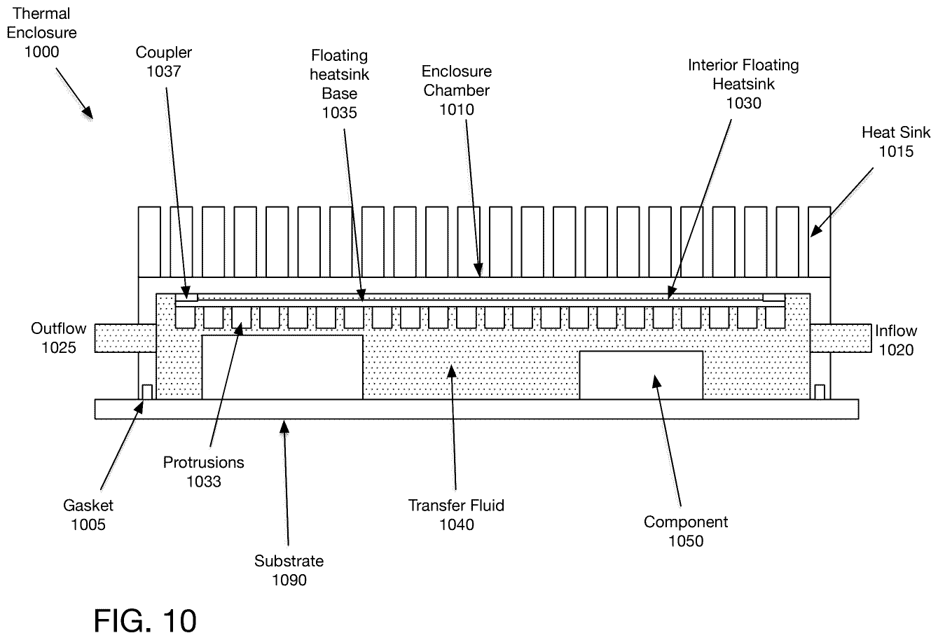

FIG. 10 illustrates one embodiment of the enclosure with a floating heatsink inside the enclosure. In this configuration, the enclosure 1000 includes an enclosure chamber 1010, coupled to a substrate 1090, to provide thermal management for components 1050 using transfer fluid 1040. The transfer fluid 1040 flows through the enclosure chamber 1010, through inflow 1020 and outflow 1025. The enclosure 1000 is sealed against the substrate 1090 using gasket 1005.

The enclosure 1000 optionally includes a heatsink 1015, to provide additional cooling using air. In this configuration, there is an interior floating heatsink 1030 within the enclosure chamber 1010. The floating heatsink 1030 may be coupled to the interior top of the enclosure 1000. The floating heatsink 1030 provides more surface for cooling the transfer fluid 1040 within the enclosure chamber 1010. In some embodiments, the floating heatsink 1030 includes a plurality of protrusions 1033, such as fins, fingers, or pin, which extend into the chamber 1010.

The individual protrusions 1033 may be coupled to a base 1035. In this embodiment, the floating heatsink base 1035 is coupled to the top of the enclosure chamber 1010. In some embodiments, the base 1035 may be coupled to the top of the chamber 1010 with a plurality of offset couplers 1037, which create a space between the top of the chamber and the bottom of the heatsink base 1035. The base 1035 may have holes, open spaces, or perforations through which the transfer fluid 1040 can pass. In some embodiments, the floating heatsink 1030 can therefore separate the gaseous transfer fluid 1040 from the liquid form.

In some other embodiments, the protrusions may be directly coupled to the interior of the chamber 1010 without a separate heatsink base 1035. The protrusions 1033 may be integral with the chamber top, in some embodiments. In some other embodiments, the floating heatsink base 1035 may be coupled to the top of the chamber, without an offset.

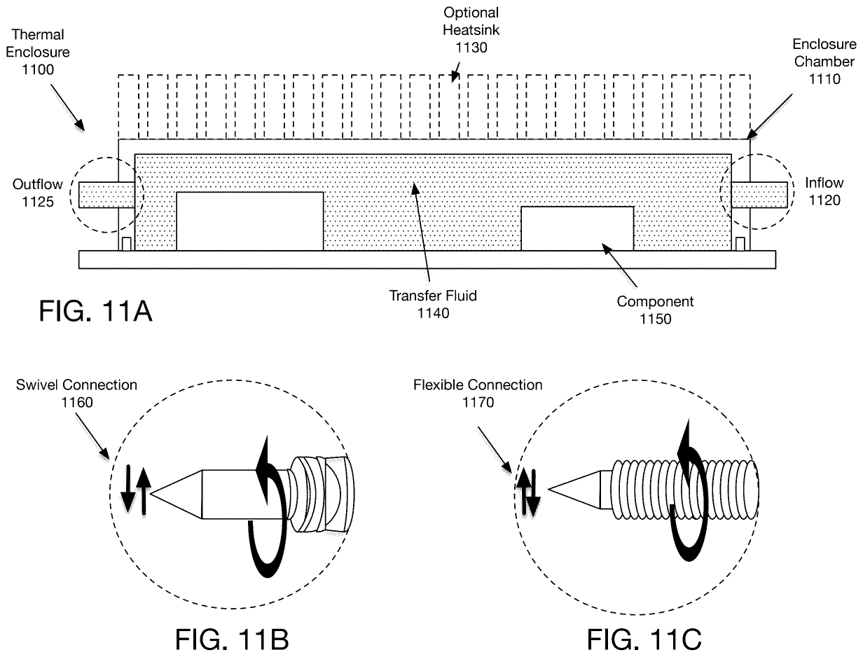

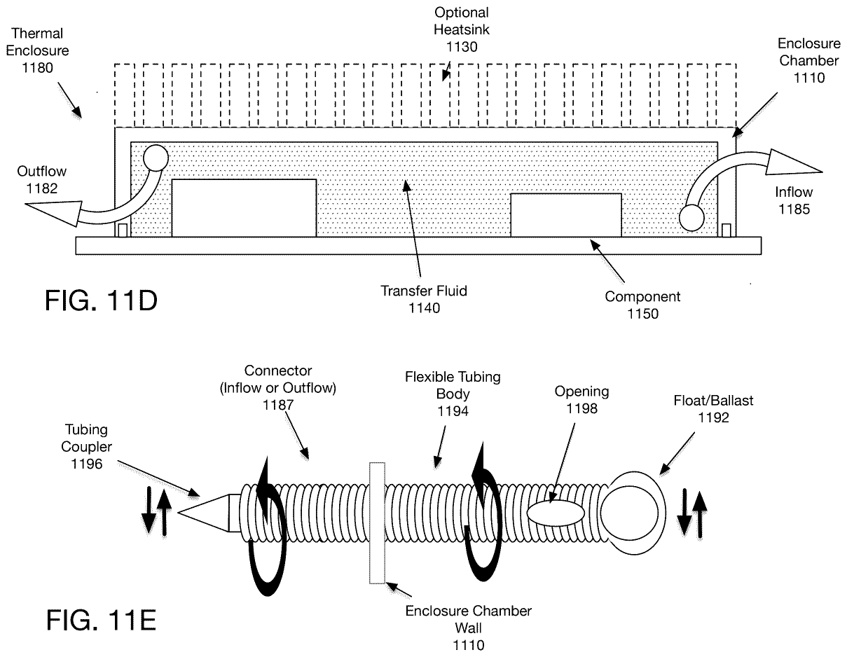

FIG. 11A illustrates one configuration of a connection for the coupling for rotation insensitivity. The thermal enclosure 1100 includes an enclosure chamber 1110, filled with transfer fluid 1140. There is an inflow 1120 and outflow 1125 for the transfer fluid 1140. The inflow 1120 and/or outflow 1125 may be designed to provide rotational insensitivity so that the coupling to the enclosure 1100 is more flexible, regardless of the orientation of the enclosure within a server or other device.

FIG. 11B illustrates one configuration of a rotation insensitive connection for the coupling. This configuration provides a swivel connection 1160 to which the tube or manifold may be coupled for in-coupling and/or out-coupling the transfer fluid 1140. The swivel connection may be a ball joint as shown in FIG. 11B. Alternatively, as shown in FIG. 11C, the connection may be a flexible connection 1170, which can be moved so that the inflow and/or outflow connections can be placed without straining the enclosure 1100, the inflow/outflow connections, or the manifold or tubing, based on the orientation of the enclosure.

FIGS. 11D and 11E illustrate one configuration of a flexible connection with an adjustable weight end to move the intake to the bottom, and the outflow to a top of the enclosure.

FIG. 11D illustrates the thermal enclosure 1180 including the enclosure chamber 1110 and the inflow/outflow 1182/1185, which are in this case flexible tubing. The enclosure 1180 includes components 1150 which are thermally managed using transfer fluid 1140 and may include an optional heatsink 1130. The transfer fluid 1140 enters the enclosure 1180 through inflow connection 1185 and leaves the enclosure through outflow connection 1182. FIG. 11E illustrates the flexible tubing based inflow/outflow connection 1187. The connection 1187 includes a body made of flexible tubing 1194 with a coupler 1196 to couple to external tubing or manifold outside the enclosure. The opposite end of the inflow/outflow connection 1187 is a float/ballast 1192. In one embodiment, the float/ballast 1192 may have any shape and may be filled with air or vacuum when acting as a float, or with a heavier material, when acting as a ballast. When the float/ballast 1192 is acting as a float, it is designed to rise to the top of the enclosure. When the float/ballast 1192 is acting as a ballast, it is designed to drop to the bottom of the enclosure. In one embodiment, the inflow connection 1185 uses a ballast, such that inflowing transfer fluid 1140 enters the enclosure at a bottom of the enclosure. The outflow connection 1182 uses a float, such that outflowing transfer fluid leaves from the top of the enclosure. The tubing body 1194 and/or float/ballast portion 1192 include one or more openings 1198, so that the transfer fluid 1140 can flow through the connector 1187.

The connector crosses the wall of the enclosure chamber 1110. In some embodiments, the portion of the connector 1187 which crosses the wall is glued into the wall, such that the portions of the flexible tubing body 1194 inside and outside the chamber move independently. The interior moves based on the use of a float/ballast, while the exterior moves based on the configuration of the tubing to which the tubing coupler 1196 is connected.

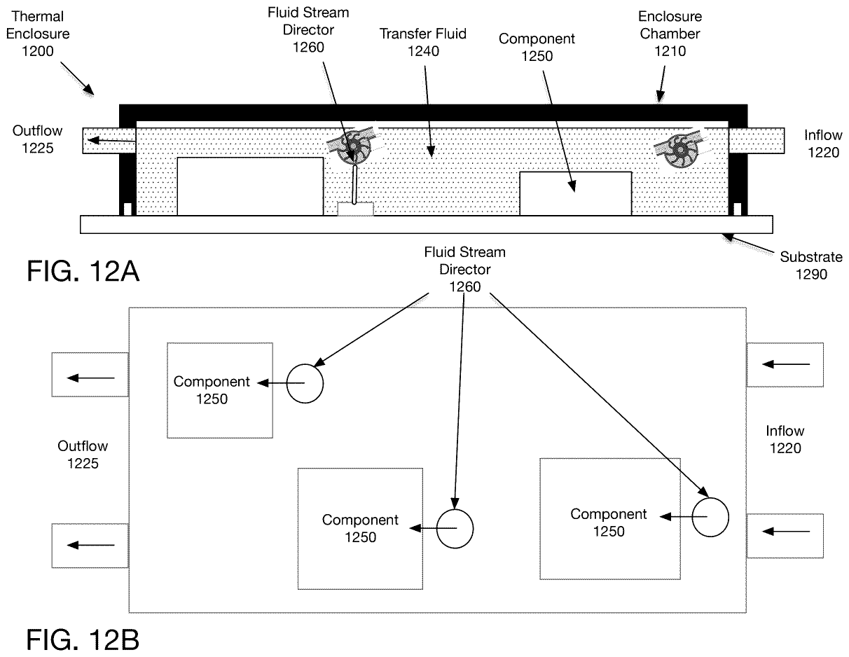

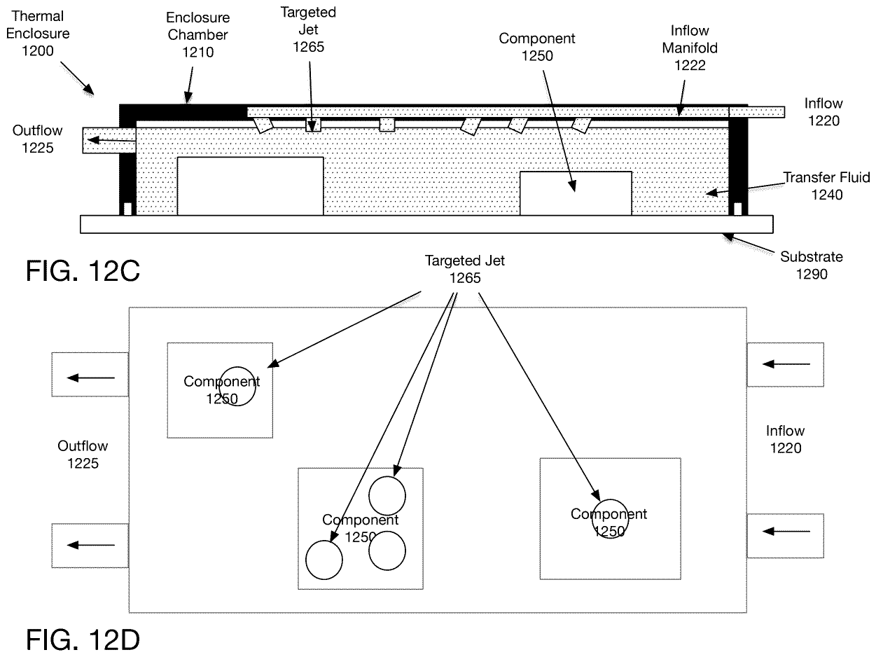

FIGS. 12A and 12B illustrates one embodiment of the system including fluid stream directors for directing flow at components within the enclosure. In this configuration, the enclosure 1200 includes an enclosure chamber 1210. The chamber 1210 encloses one or more components 1250, which are thermally managed using transfer fluid 1240. The transfer fluid 1240 enters through in-flow 1220 and exits through outflow 1225.

The system includes one or more fluid stream directors 1260. The fluid stream directors 1260 are designed to direct the transfer fluid to the top of the components 1250. In one embodiment, each component which is cooled has an associated director 1260. In another embodiment, a subset of the components may be targeted.

In some embodiments, the fluid stream director 1260 may be a rotary vane pump. The rotary vane pump may be coupled to the top of the enclosure, in some embodiments. In some other embodiments, the rotary vane pump may be coupled to the socket or frame supporting the corresponding component. The pumps may be vacuum pumps, such as vane pumps, circulation pumps, such as gear pumps, liquid ring pumps, peristaltic pumps, jet pumps, or another type of pump.

In some embodiments, the fluid stream director 1260 may be supported by a structure rising from the substrate 1290. In some embodiments, there may be a control circuit on the substrate 1290, to control the fluid stream directors 1260. The fluid stream directors may be selectively engaged. In this configuration, a power directed to the fluid stream director may be controlled based on the cooling/heating needs of the corresponding component. For example, if a particular GPU or CPU is running hot, the fluid stream director 1260 may direct additional transfer fluid 1240 to the component. The use of fluid stream directors not only ensures additional cooling capacity but can also be used to avoid the buildup of a gaseous layer around a component, due to the transfer fluid turning to gas when contacting the hot component. By directing a stream of liquid transfer fluid to the top of the component, any such buildup can be disrupted.

The above embodiments of enclosures may be utilized in various combinations. For example, the fluid stream director may be used in any of the previously described enclosures, similarly the heatsinks (interior and exterior) may be used with any of the other configurations. Additionally, the foam and/or wicking material may be used in conjunction with other configuration changes.

FIGS. 12C and 12D illustrate one embodiment of the system including targeted jets for directing flow at components within the enclosure. In this configuration, the transfer fluid inflow enters the enclosure chamber 1210 through an inflow manifold 1222 and enters the chamber through one or more targeted jets 1265. The targeted jets 1265 target the transfer fluid to particular locations, for example on components that are producing heat. In some embodiments, the targeted jets 1265 may include pumps and/or valves so that the flow can be controlled on a per-output basis.

Using targeted jets 1265, in some embodiments, the flow volume directed at components, or parts of components, may be varied. For example, in an enclosure that includes a graphics processing unit (GPU) and central processing unit (CPU), when graphics-intensive work is being done, causing the GPU to run hotter, the targeted jets 1265 (controlled by pumps and/or valves) can direct more of the flow toward the GPU. In some embodiments, only a portion of the incoming transfer fluid through inflow connection 1220 is directed through targeted jets 1265, while another portion of the incoming transfer fluid enters the chamber without being directed through targeted jets.

In some embodiments, the targeted jets 1265 is customized for the specific layout of components on the substrate 1290. A single component may have multiple targeted jets 1265 directed to it, in some embodiments. In some embodiments, a single component may have multiple areas that have different temperatures during operation. For example, a large system-on-a-chip component may have some areas that run hotter than others. In some embodiments, the targeted jets 1265 may be directed to those hotter areas.

In some embodiments, sensors within the enclosure 1200 are used for directing the targeted jets. In some embodiments, telemetry data collected by the system running a data center or thermal management system may be used. In some embodiments an external telemetry system receives data from the components within the enclosure and shares that data with the thermal management system to optimize the direction of the transfer fluid. As discussed above, this enclosure may be part of a larger system with multiple enclosures and multiple devices. In some embodiments, the incoming flow of transfer fluid is managed across a plurality of enclosures, to ensure that each of the components in each of the enclosures is maintained at a temperature range that is within optimal operating parameters for that component.

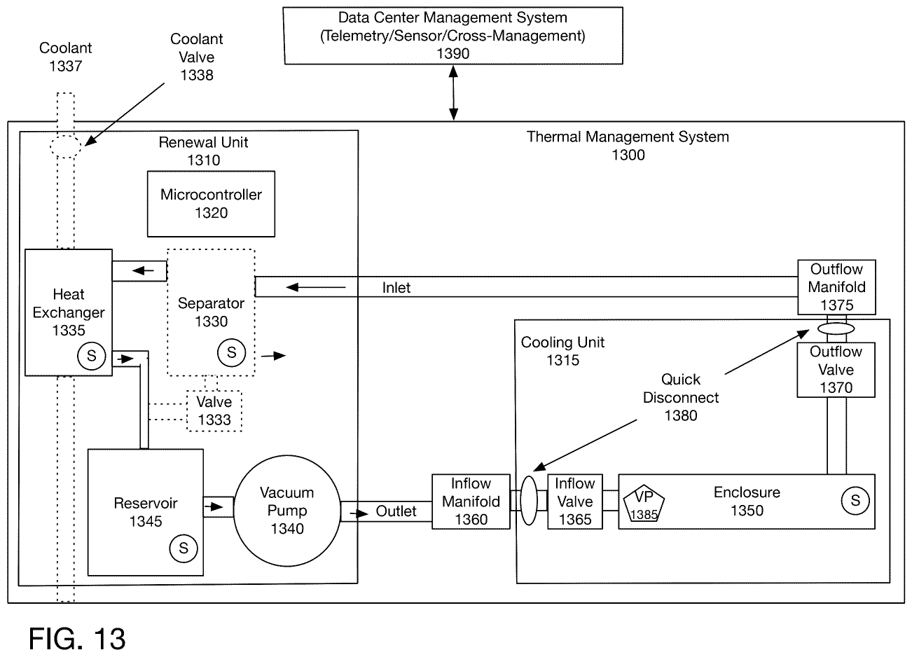

FIG. 13 is a block diagram an exemplary configuration of the thermal management system. This illustrates what happens with the transfer fluid outside of the enclosure.

The thermal management system 1300 in one embodiment is considered to include the entire circulatory system or flow path of the system including the enclosure which delivers the cooling to individual enclosures. The thermal management system in some embodiments includes a renewal unit 1310. Although only a single cooling unit 1315 is shown, it should be understood that a standard thermal management system may support any number of cooling units 1315. The cooling unit 1315 is designed to provide thermal management to ensure that components within the enclosure 1350 operate at their optimal temperature range. This may include cooling the components as well as heating them, depending on operational circumstances.

The renewal unit 1310 in one embodiment includes a heat exchanger 1335, a reservoir 1345, and a vacuum pump 1340. The renewal unit 1310 may also include a separator 1330, to separate gaseous from liquid transfer fluid and direct the liquid through valve 1333 directly to reservoir 1345. Although only a single renewal unit 1310 is shown, a system may include multiple renewal units, as well as multiple cooling units 1315. The transfer fluid operates under a partial vacuum, managed by vacuum pump 1340. In some embodiments, secondary vacuum pumps 1385 to increase or vary the vacuum level in the system may be located outside the renewal unit 1310. The secondary vacuum pumps 1385 may be located within a cooling unit 1315, for example within an enclosure 1350, within the outflow manifold 1375 and/or inflow manifold 1360, or the outflow valve 1365 and/or inflow valve 1370. In some embodiments, each cooling unit 1315 may have an associated secondary vacuum pump 1385. In other embodiments, only a subset of cooling units may have an associated secondary vacuum pumps 1385. In some embodiments, the secondary vacuum pump 1385 is a diaphragm pump.

The microcontroller 1320 receives data from sensors and potentially from components and/or a data center management system 1390 and controls the components within the renewal unit 1310 as well as the flow of transfer fluid to the enclosure 1350. The microcontroller also controls the flow of a coolant 1337 which is used by heat exchanger 1335, in some embodiments, using a coolant valve 1338. The data center management system 1390 may receive data from various systems and sensors, including potentially components within enclosures, environmental sensors, etc. The data center management system 1390 may provide information to the microcontroller 1320, which in turn controls the flow of transfer fluid through the system, and to individual enclosures and optionally individual components or even component parts within enclosures. The thermal management system 1300 may in turn provide data from its sensors and analytics to the data center management system 1390. This enables integration of the thermal management system 1300 into a managed data center, taking advantage of the telemetry and control data available.

One or more of the components of the thermal management system 1300 may include sensors(S) which may measure one or more of pressure, temperature, and flow speed. In this illustration, each of the parts of the system includes a sensor. However, in other implementations there may not be sensors in each component. Additionally, in some embodiments there may be separate sensors in the transfer tubing in the inlet, outlet, or between the components. In one embodiment, there are at least two sensors in the system, a temperature sensor for the inlet to determine the temperature of the used transfer fluid, and one in the outlet to determine the temperature of the renewed transfer fluid. In some embodiments, there is also a pressure sensor in one or more of the reservoir 1345, enclosure 1350, vacuum pump 1340, and/or transfer tubing. In addition to sensors, there may also be telemetry data provided by components within the system to data center management system 1390. In some embodiments, the specific distribution of data sources may depend on what data is available through other sources. For example, in some embodiment's, the thermal management system 1300 may include only transfer fluid flow sensors, while other data including temperature data and pressure data may come from other sources. Alternatively, the thermal management system 1300 may be independent, with external data sources, and may include more sensors.

The outlet from the renewal unit 1310 passes to an inflow manifold 1360 which distributes the transfer fluid to the individual cooling units. The transfer fluid flows through an inflow valve 1365. In one embodiment, the inflow valve 1365 is a valve which is used to control the flow rate to the cooling unit 1315. The valve may be a solenoid valve in some embodiments. In some embodiments, the control may be Pulse Width Modulation (PWM) to control flow rate to individual enclosures. The used transfer fluid then exits through an outflow valve 1370 to an outflow manifold 1375, which returns the used transfer fluid to the renewal unit 1310. In one embodiment, the inflow valve 1365 and outflow valve 1370 are located at the end of the manifold, outside the device. In another embodiment, the valves are within the cooling unit, or at the cooling unit intake tubing.

Controlling the inflow and outflow of the transfer fluid for each cooling unit can be used to adjust the pressure, and thus the boiling point of the transfer fluid within the unit. For each individual cooling unit within the system, the boiling point can be raised or lowered compared to the rest of the system, by modulating the length of time that the inflow valve and the outflow valve are open. This enables granularity of control to customize the cooling for each cooling unit based on the heating/cooling needs of the components. It also enables the system to reduce the cost of cooling, by reserving the highest vacuum (lowest boiling point) for the components operating at the highest temperature and thus needing the most cooling, while still providing adequate cooling for other server cooling units. Additionally, as noted previously, a single device may have multiple cooling units, enabling differential cooling across a single device. This type of granular control of pressure and flow rate provides significant benefits, including reduced cooling costs, reduced power use, reduced water use, and improved operation for the components in the cooling units.

As discussed above, these may be enclosures of various types. In various embodiments, each enclosure 1350 has a separate inflow valve 1365 which controls the flow to the individual enclosure 1350. This allows individual control of the flow rate by the renewal unit 1310. In one embodiment, the system further includes a quick disconnect 1380 that enables the enclosure to be disconnected from the transfer fluid flow, when a device is replaced or needs repair. In one embodiment, the microcontroller 1320 controls the quick disconnect 1380, which enables a disconnection that removes most of the transfer fluid from the enclosure 1350 by first closing the inflow valve 1365, and then closing the outflow valve 1370 after the transfer fluid has been drained from the enclosure 1350.

The different features and configurations of enclosures described in the Specification may be used in various combinations. For example, enclosure may include component contact areas for some components, while others do not have such contact areas. The foam or wicking materials described may be present in combination with other features, such as the contact areas, the thermal riser, a heatpipe, the rotation insensitive connections, etc. Similarly, the two-part enclosure or plastic enclosure may be combined with any of the additional configurations shown, such as the heatpipe, wicking materials, foams, etc. The rotation insensitive connections described may be used with any of the enclosure configurations as well. Similarly, targeted flow may be combined with various other configurations. Thus, the improvements to the enclosure described should be considered as a combination of features which may be selected to optimize the thermal management system for the particular use.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

We claim:

1. A cooling system to provide thermal management comprising:
a substrate;
an enclosure including an inflow connection and an outflow connection;
a silkscreened pattern printed on the substrate for positioning and to provide sealing;
a gasket seated on a top side of the substrate over the silkscreened pattern, the gasket encircling one or more components mounted on the substrate;
wherein the gasket and the silkscreened pattern provide a leakproof connection between the enclosure and the substrate when the enclosure is fastened to the substrate;
a transfer fluid to flow into the enclosure through the inflow connection, and out of the enclosure through the outflow connection, the transfer fluid within the sealed enclosure contacting the one or more components mounted on the substrate and providing thermal management.

2. The cooling system of claim 1, further comprising:
a component contact area coupled to an interior of the enclosure and in physical contact with a component, to provide direct heat transfer between the component and the enclosure.

3. The cooling system of claim 1, wherein the transfer fluid is a phase changing fluid, and the outflow connection is to remove gaseous transfer fluid.

4. The cooling system of claim 3, further comprising:
channels in an interior top of the enclosure to provide a path for the gaseous transfer fluid to move to the outflow connection.

5. The cooling system of claim 1, further comprising:
foam fill in an interior of the enclosure, the foam fill leaving a portion of the interior open for gaseous transfer fluid, the foam fill to prevent sloshing of the transfer fluid within the enclosure; and
cut-outs in the foam fill over each component, to enable the gaseous transfer fluid to move to a top of the enclosure.

6. The cooling system of claim 1, further comprising:
wicking material in an interior of the enclosure, the wicking material providing nucleation points for the transfer fluid.

7. The cooling system of claim 6, wherein the wicking material fills the interior of the enclosure.

8. The cooling system of claim 6, wherein the wicking material surrounds a component and includes gas paths to enable gaseous transfer fluid to escape.

9. The cooling system of claim 8, further comprising:
a thermal riser including the wicking material between the component and the substrate to provide cooling to a bottom of the component.

10. The cooling system of claim 1, further comprising:
one or more targeted jets to direct flow of the transfer fluid to an area within the enclosure.

11. The cooling system of claim 1, wherein the enclosure is made of a plastic material.

12. The cooling system of claim 1, wherein the enclosure comprises an enclosure base coupled to the substrate and an enclosure lid coupled to the enclosure base.

13. The cooling system of claim 1, wherein one or both of the inflow connection and the outflow connection comprise rotation insensitive connectors.

14. The cooling system of claim 13, wherein the rotation insensitive connectors comprise one of: a flexible connection or a swivel connection.

15. The cooling system of claim 14, wherein the flexible connection further comprises a tubing coupler on an outside of the enclosure, a flexible portion on an inside of the enclosure, and a float/ballast to move an end of the flexible connection to one of: a bottom of the enclosure when the float/ballast acts as a ballast, or a top of the enclosure when the float/ballast acts as a float.

16. The cooling system of claim 1, further comprising:
a renewal unit comprising a microcontroller to control a flow of the transfer fluid into the enclosure through the inflow connection, and out of the enclosure through the outflow connection.

17. A thermal management system:
a cooling unit comprising:
a substrate;
an enclosure including an inflow connection and an outflow connection, the enclosure filled with a transfer fluid contacting one or more components mounted on the substrate;
a silkscreened pattern printed on the substrate for positioning and to provide sealing;
a gasket seated on a top side of the substrate over the silkscreened pattern, the gasket encircling one or more components mounted on the substrate;
wherein the gasket and the silkscreened pattern provide a leakproof connection between the enclosure and the substrate when the enclosure is fastened to the substrate;
a renewal unit comprising a microcontroller to control a flow of the transfer fluid into the enclosure through the inflow connection, and out of the enclosure through the outflow connection.

18. The thermal management system of claim 17, wherein the transfer fluid is a phase changing fluid, and a phase change of the transfer fluid is used to cool the one or more components in the enclosure, and wherein the outflow connection is to remove gaseous transfer fluid.

19. The thermal management system of claim 17, further comprising: a plurality of cooling units coupled to the renewal unit, such that the renewal unit cools the transfer fluid collected from the plurality of cooling units.

20. The thermal management system of claim 17, further comprising:
a fluid stream director to selectively direct the transfer fluid to a particular component within the enclosure, the fluid stream director controlled by the microcontroller in the renewal unit.
